(19) United States
(12) Patent Application Publication
(10) Pub. No.: US 2023/0223291 A1
(43) Pub. Date: Jul. 13, 2023

(54) MEMBER FOR SEMICONDUCTOR MANUFACTURING APPARATUS

(71) Applicant: NGK Insulators, Ltd., Nagoya-City (JP)

(72) Inventors: Seiya INOUE, Handa-City (JP); Tatsuya KUNO, Nagoya-City (JP); Natsuki HIRATA, Nagoya-City (JP)

(73) Assignee: NGK Insulators, Ltd., Nagoya-City (JP)

(21) Appl. No.: 18/048,967

(22) Filed: Oct. 24, 2022

(30) Foreign Application Priority Data
Jan. 7, 2022 (JP) 2022-001652

(51) Int. Cl. H01L 21/683; H01J 37/32

(52) U.S. Cl. CPC H01L 21/6833; H01J 37/32724; H01J 37/3244; H01J 2237/2007

(57) ABSTRACT

A member for semiconductor manufacturing apparatus includes a ceramic plate that has an upper surface including a wafer placement surface and resin porous plugs that have upper surfaces that are exposed from the wafer placement surface. The resin porous plugs are press-fitted and secured in plug insertion holes that extend through the ceramic plate in an up-down direction and allow gas to flow.

### BACKGROUND OF THE INVENTION

### 1. Field of the Invention

The present invention relates to a member for semiconductor manufacturing apparatus.

### 2. Description of the Related Art

A known member for semiconductor manufacturing apparatus includes an electrostatic chuck that has an upper surface including a wafer placement surface. For example, an electrostatic chuck in PTL 1 that includes a ceramic plate on which a wafer is attracted and held, a through-hole that is formed in the ceramic plate, and a porous plug that is disposed in the through-hole is disclosed. To manufacture such an electrostatic chuck, the ceramic plate is first manufactured by firing a green sheet that contains an electrostatic electrode, and the through-hole is formed in the ceramic plate. Subsequently, ceramic mixture paste that contains ceramic particles and particles to be annihilated by firing is filled in the through-hole and is heated to a predetermined temperature. Consequently, the ceramic particles in the mixture are fired, and the particles to be annihilated by firing are annihilated. In this way, the porous plug is formed in the through-hole, and the electrostatic chuck described above is obtained. As for the electrostatic chuck, helium gas is introduced into the porous plug from the outside with the wafer electrostatically attracted to the wafer placement surface. The helium gas is then supplied to a position near a back surface of the wafer, and heat conduction between the wafer and the ceramic plate is improved. At this time, the helium gas passes through pores of the porous plug, and this inhibits arc discharge from occurring near the back surface of the wafer unlike the case where helium gas passes through a through-hole in which no porous plug is present. Without a porous plug, electrons that are generated by ionization of helium are accelerated and collide with another helium, and arc discharge occurs. The porous plug inhibits arc discharge from occurring because the electrons collide with the porous plug before the electrons collide with the other helium. When the arc discharge occurs near the back surface of the wafer, the quality of the wafer changes, and the wafer cannot be used as a device, which is not preferable.

### CITATION LIST

### Patent Literature

PTL 1: Japanese Unexamined Patent Application Publication No. 2019-29384 A

### SUMMARY OF THE INVENTION

However, a firing process needs to be performed twice for the electrostatic chuck described above. That is, the firing process needs to be performed in a process of manufacturing the ceramic plate and a process of manufacturing the porous plug. For this reason, there is a problem in that manufacturing costs increase.

The present invention has been accomplished to solve the problem, and it is a main object of the present invention to provide a member for semiconductor manufacturing apparatus that includes a porous plug that allows gas to flow at low costs.

A member for semiconductor manufacturing apparatus according to the present invention includes a ceramic plate that has an upper surface including a wafer placement surface, and a resin porous plug that has an upper surface that is exposed from the wafer placement surface, that is press-fitted and secured in a plug insertion hole that extends through the ceramic plate in an up-down direction, and that allows gas to flow.

As for the member for semiconductor manufacturing apparatus, the resin porous plug that allows the gas to flow is press-fitted and secured in the plug insertion hole that extends through the ceramic plate in the up-down direction. For this reason, it is not necessary to fire the resin porous plug when the resin porous plug is secured in the plug insertion hole. Even through the resin porous plug is degraded due to the use thereof, the resin porous plug that is degraded can be easily replaced with a new resin porous plug. Accordingly, the member for semiconductor manufacturing apparatus that includes the porous plug can be provided at low costs.

In the present specification, the words “up-down”, “left-right”, and “front-rear” are used to describe the present invention in some cases, but the words “up-down”, “left-right”, and “front-rear” merely represent relative positional relationships. For this reason, the word “up-down” is changed into the word “left-right” or the word “left-right” is changed into the word “up-down” in some cases where the direction of the member for semiconductor manufacturing apparatus is changed. These cases are also included in the technical scope of the present invention.

As for the member for semiconductor manufacturing apparatus according to the present invention, the ceramic plate may include a conductive base on a lower surface, and the resin porous plug may be in contact with the conductive base. In some cases where a resin porous plug is not in contact with a conductive base, arc discharge occurs between the porous plug and the conductive base. In the case where the resin porous plug is in contact with the conductive base, however, arc discharge can be inhibited from occurring.

As for the member for semiconductor manufacturing apparatus according to the present invention, the resin porous plug may contain a dense columnar solid member that has a diameter smaller than that of the resin porous plug. Consequently, the dense columnar solid member serves as a core. Accordingly, the resin porous plug is easily press-fitted into the plug insertion hole, and the height of the upper surface of the resin porous plug can be precisely adjusted.

As for the member for semiconductor manufacturing apparatus according to the present invention, the resin porous plug may contain a dense cylindrical hollow member that has a diameter smaller than that of the resin porous plug, that is inserted from a lower surface of the resin porous plug, and that does not extend through an upper surface of the resin porous plug. Consequently, the dense cylindrical hollow member serves as a core. Accordingly, the resin porous plug is easily press-fitted into the plug insertion hole, and the height of the upper surface of the resin porous plug can be precisely adjusted. The gas mainly passes through an upper portion of the resin porous plug (a portion above the dense cylindrical hollow member), and accordingly, the pressure loss of the gas can be reduced.

As for the member for semiconductor manufacturing apparatus according to the present invention, the resin porous plug may contain a columnar porous member that has porosity higher than that of the resin porous plug. Consequently, the gas mainly passes through the columnar porous member, and accordingly, the pressure loss of the gas can be reduced.

As for the member for semiconductor manufacturing apparatus according to the present invention, the wafer placement surface may have a large number of small projections that support a wafer, and the upper surface of the resin porous plug may be lower than upper surfaces of the small projections. Consequently, the upper surface of the resin porous plug does not lift the wafer. In this case, the upper surface of the resin porous plug may be flush with a reference surface of the wafer placement surface on which the small projections are not formed or may be lower than the reference surface by 0.5 mm or less. This enables the height of a space between a back surface of the wafer and the upper surface of the resin porous plug to be decreased, and arc discharge can be prevented from occurring in the space. The height of the reference surface may change for every small projection. The height of the reference surface may be equal to the height of the bottom surface of the small projection nearest to the plug insertion hole.

### BRIEF DESCRIPTION OF THE DRAWINGS

FIG. 1 illustrates a vertical cross-sectional view of a member 10 for semiconductor manufacturing apparatus.

FIG. 2 illustrates a plan view of a ceramic plate 20.

FIG. 3 illustrates a partially enlarged view of a part in FIG. 1.

FIGS. 4A to 4C illustrate processes of manufacturing the member 10 for semiconductor manufacturing apparatus.

FIG. 5 illustrates a vertical cross-sectional view of a resin porous plug 150.

FIG. 6 illustrates a vertical cross-sectional view of a resin porous plug 250.

FIG. 7 illustrates a vertical cross-sectional view of a resin porous plug 350.

FIG. 8 illustrates another example of the vertical cross-sectional view of the resin porous plug 350.

FIG. 9 illustrates a vertical cross-sectional view of a resin porous plug 550.

FIG. 10 illustrates a vertical cross-sectional view of a resin porous plug 650.

FIG. 11 illustrates another example of a vertical cross-sectional view of a resin porous plug 50.

### DETAILED DESCRIPTION OF THE INVENTION

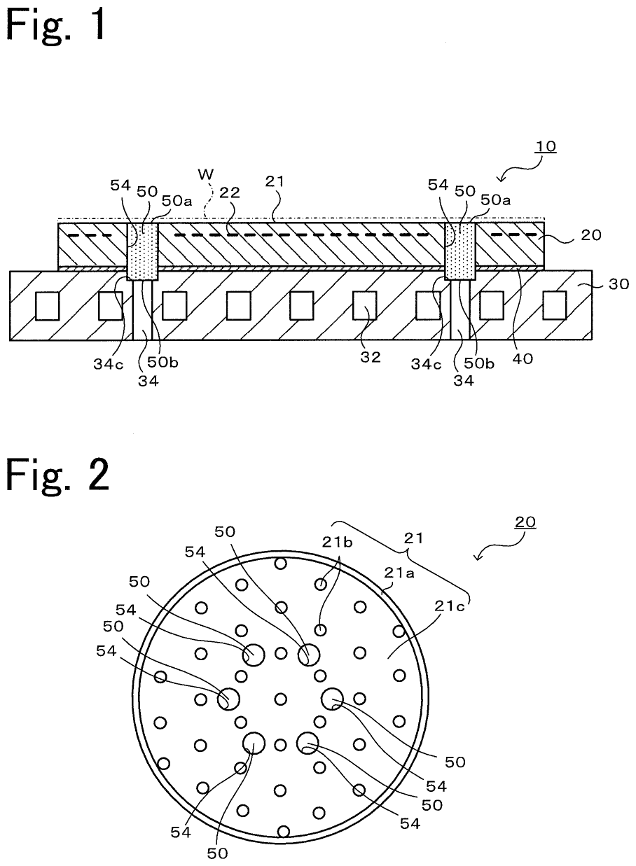

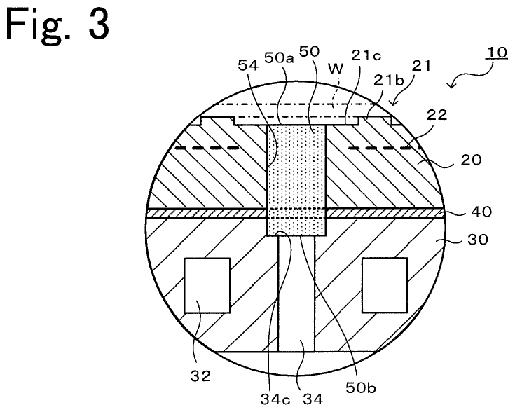

A preferred embodiment of the present invention will now be described with reference to the drawings. FIG. 1 illustrates a vertical cross-sectional view of a member 10 for semiconductor manufacturing apparatus. FIG. 2 illustrates a plan view of a ceramic plate 20. FIG. 3 illustrates a partially enlarged view of a part in FIG. 1.

The member 10 for semiconductor manufacturing apparatus includes the ceramic plate 20, a cooling plate 30, a metal joining layer 40, and resin porous plugs 50.

The ceramic plate 20 is a ceramic disk (having, for example, a diameter of 300 mm and a thickness of 5 mm) such as an alumina sintered body or an aluminum nitride sintered body. An upper surface of the ceramic plate 20 is a wafer placement surface 21. The ceramic plate 20 contains an electrode 22. As illustrated in FIG. 2, a seal band 21a is formed on the wafer placement surface 21 of the ceramic plate 20 along an outer edge, and multiple circular small projections 21b are formed on the entire surface. The seal band 21a and the circular small projections 21b have the same height, and the height thereof is, for example, several atm to several tens of μm. The electrode 22 is a mesh electrode that is used as an electrostatic electrode and that has a flat plate shape, and a direct voltage can be applied thereto. When the direct voltage is applied to the electrode 22, a wafer W is attracted and secured to the wafer placement surface 21 (specifically, an upper surface of the seal band 21a and upper surfaces of the circular small projections 21b) due to electrostatic attraction force. When applying the direct voltage ends, the wafer W that is attracted and secured to the wafer placement surface 21 is released. A portion of the wafer placement surface 21 on which the seal band 21a and the circular small projections 21b are not formed is referred to as a reference surface 21c.

The cooling plate 30 is a disk (a disk that has a diameter equal to or larger than the diameter of the ceramic plate 20) that has good thermal conductivity. The cooling plate 30 contains a refrigerant flow path 32 through which refrigerant circulates and gas holes 34 in which gas is supplied to the resin porous plugs 50. The refrigerant flow path 32 is formed in a one-stroke pattern from an inlet to an outlet over the entire cooling plate 30 in a plan view. Each of the gas holes 34 is a hole with a step and has an upper opening edge around which a step portion 34c is located. Examples of the material of the cooling plate 30 include a metal material and a metal matrix composite material (MMC). Examples of the metal material include Al, Ti, Mo, or an alloy thereof. Examples of the MMC include a material containing Si, SiC, and Ti (also referred to as SiSiCTi) and a material obtained by impregnating a SiC porous body with Al and/or Si. A material that has a thermal expansion coefficient close to that of the ceramic plate 20 is preferably selected as the material of the cooling plate 30. The cooling plate 30 is also used as a RF electrode. Specifically, an upper electrode (not illustrated) is disposed above the wafer placement surface 21, and plasma is generated when high-frequency power is supplied between parallel flat plate electrodes that include the upper electrode and the cooling plate 30.

The metal joining layer 40 joins the lower surface of the ceramic plate 20 and the upper surface of the cooling plate 30 to each other. The metal joining layer 40 is formed by, for example, TCB (Thermal compression bonding). The TCB is a known method of compressing and joining two members in a state in which the two members to be joined interpose a metal joining material therebetween and are heated to a temperature equal to or less than the solidus temperature of the metal joining material. The metal joining layer 40 and the cooling plate 30 according to the present embodiment correspond to a conductive base according to the present invention.

The resin porous plugs 50 are press-fitted and secured in plug insertion holes 54. The plug insertion holes 54 extend through the ceramic plate 20 and the metal joining layer 40 in an up-down direction and are columnar holes that reach the step portions 34c that are disposed along the upper opening edges of the gas holes 34 of the cooling plate 30 and that are annular. The plug insertion holes 54 are formed at multiple positions (for example, multiple positions equally spaced from each other in a circumferential direction) in the ceramic plate 20. The resin porous plugs 50 are columnar resin porous members that allow the gas to flow in the up-down direction and that are composed of an electrical insulation material. The resin porous plugs 50 can be composed of a commercially available resin porous material such as PTFE, PPS, PEEK, or PEKK. Upper surfaces 50a of the resin porous plugs 50 are exposed from upper openings of the plug insertion holes 54 and are on the same plane as the reference surface 21c. The word “same” includes not only a case of being completely the same but also a case of being substantially the same (for example, a case of being within tolerance) (the same is true for the following description). The resin porous plugs 50 are press-fitted from the upper openings of the plug insertion holes 54 until lower surfaces 50b come in contact with the annular step portions 34c that define lower surfaces of the plug insertion holes 54 and are secured.

An example of the use of the member 10 for semiconductor manufacturing apparatus thus configured will now be described. The wafer W is first placed on the wafer placement surface 21 with the member 10 for semiconductor manufacturing apparatus installed in a chamber not illustrated. The pressure of the chamber is decompressed by a vacuum pump and is adjusted such that a predetermined degree of vacuum is achieved. A direct voltage is applied to the electrode 22 of the ceramic plate 20 to generate electrostatic attraction force, and the wafer W is attracted and secured to the wafer placement surface 21 (specifically, the upper surface of the seal band 21a and the upper surfaces of the circular small projections 21b). Subsequently, a reactive gas atmosphere at a predetermined pressure (for example, several tens of Pa to several hundreds of Pa) is created in the chamber. In this state, a high-frequency voltage is applied between an upper electrode, not illustrated, on a ceiling portion in the chamber and the cooling plate 30 of the member 10 for semiconductor manufacturing apparatus, and plasma is generated. The surface of the wafer W is processed by the generated plasma. The refrigerant circulates through the refrigerant flow path 32 of the cooling plate 30. Backside gas is introduced into the gas holes 34 from a gas tank not illustrated. Heat conduction gas (such as helium) is used as the backside gas. The backside gas passes through the gas holes 34 and the resin porous plugs 50, is supplied to a space between the back surface of the wafer W and the reference surface 21c of the wafer placement surface 21, and is sealed. The backside gas enables heat conduction between the wafer W and the ceramic plate 20 to be efficient.

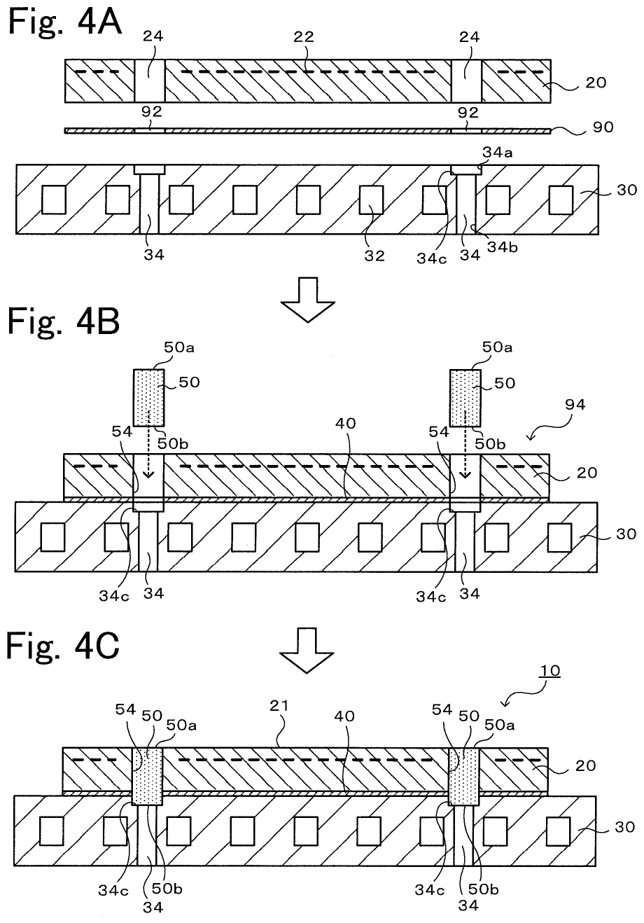

An example of manufacturing the member 10 for semiconductor manufacturing apparatus will now be described with reference to FIGS. 4A to 4C. FIGS. 4A to 4C illustrate processes of manufacturing the member 10 for semiconductor manufacturing apparatus. The ceramic plate 20, the cooling plate 30, and a metal joining material 90 are first prepared (FIG. 4A). The ceramic plate 20 contains the electrode 22 and has through-holes 24 that partly form the plug insertion holes 54. The cooling plate 30 contains the refrigerant flow path 32 and has the gas holes 34 that extend therethrough in the up-down direction. The gas holes 34 have hole upper portions 34a that have a large diameter, hole lower portions 34b that have a small diameter, and the step portions 34c that define boundaries between the hole upper portions 34a and the hole lower portions 34b. The metal joining material 90 has through-holes 92 that finally partly form the plug insertion holes 54.

The lower surface of the ceramic plate 20 and the upper surface of the cooling plate 30 are joined to each other by using the TCB, and a joined body 94 is obtained (FIG. 4B). The TCB is performed, for example, in the following manner. The metal joining material 90 is put between the lower surface of the ceramic plate 20 and the upper surface of the cooling plate 30 (FIG. 4A), and a layered body is consequently obtained. At this time, these are stacked such that the through-holes 24 of the ceramic plate 20, the through-holes 92 of the metal joining material 90, and the gas holes 34 of the cooling plate 30 are coaxial with each other. The layered body is compressed and joined at a temperature equal to or less than the solidus temperature of the metal joining material 90 (for example, no less than a temperature obtained by subtracting 20° C. from the solidus temperature and no more than the solidus temperature), and subsequently, the temperature is returned to the room temperature. Consequently, the metal joining material 90 becomes the metal joining layer 40, through-holes 24 and 92 and the hole upper portions 34a of the gas holes 34 become the plug insertion holes 54, and the joined body 94 in which the ceramic plate 20 and the cooling plate 30 are joined to each other by the metal joining layer 40 is obtained. At this time, an Al—Mg joining material or an Al—Si—Mg joining material can be used as the metal joining material. For example, in the case where the Al—Si—Mg joining material is used for the TCB, the layered body is compressed while being heated in a vacuum atmosphere. The thickness of the metal joining material 90 is preferably about 100 μm.

Subsequently, the resin porous plugs 50 are prepared. The diameters of the resin porous plugs 50 are slightly larger than the diameters of the plug insertion holes 54. The resin porous plugs 50 are press-fitted from the upper openings of the plug insertion holes 54 until the lower surfaces 50b come in contact with the annular step portions 34c that define the lower surfaces of the plug insertion holes 54 and are secured. The resin porous plugs 50 have higher elasticity than a ceramic material and can be accordingly press-fitted and secured. The resin porous plugs 50 are designed such that the upper surfaces 50a are on the same plane as the reference surface 21c (see FIG. 3) of the wafer placement surface 21 with the lower surfaces 50b being contact with the step portions 34c. In this way, the member 10 for semiconductor manufacturing apparatus is obtained (FIG. 4C).

As for the member 10 for semiconductor manufacturing apparatus described in detail above, the resin porous plugs 50 that allow the gas to flow are press-fitted and secured in the plug insertion holes 54 that extend through the ceramic plate 20 in the up-down direction. For this reason, it is not necessary to fire the resin porous plugs 50 when the resin porous plugs 50 are secured in the plug insertion holes 54. Even through the resin porous plugs 50 are degraded due to the use thereof, the resin porous plugs 50 that are degraded can be easily replaced with new resin porous plugs 50. Accordingly, the member 10 for semiconductor manufacturing apparatus that includes the porous plugs can be provided at low costs.

In the case where the resin porous plugs 50 are press-fitted and secured at the end of the manufacturing process, a subsequent process of cleaning the resin porous plugs 50 can be omitted.

The resin porous plugs 50 are in contact with the conductive base (the metal joining layer 40 and the cooling plate 30). In some cases where the resin porous plugs 50 are not in contact with the conductive base, arc discharge occurs between the resin porous plugs 50 and the conductive base. In the case where the resin porous plugs 50 are in contact with the conductive base, however, arc discharge can be inhibited from occurring.

The upper surfaces 50a of the resin porous plugs 50 are lower than the upper surface of the seal band 21a and the upper surfaces of the circular small projections 21b. For this reason, the upper surfaces 50a of the resin porous plugs 50 do not lift the wafer W.

The upper surfaces 50a of the resin porous plugs 50 are flush with the reference surface 21c of the wafer placement surface 21. For this reason, the heights of spaces between the lower surface of the wafer W and the upper surfaces 50a of the resin porous plugs 50 can be decreased. Accordingly, arc discharge can be prevented from occurring in the spaces.

It goes without saying that the present invention is not limited to the embodiment described above and can be carried out in various aspects within the technical scope of the present invention.

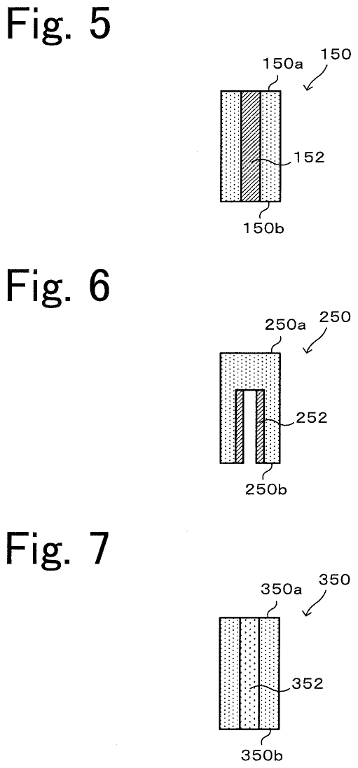

Resin porous plugs 150 to 350 illustrated in FIG. 5 to FIG. 8 may be used instead of the resin porous plugs 50 according to the embodiment described above.

The resin porous plug 150 in FIG. 5 contains a dense columnar solid member 152 that has a diameter smaller than that of the resin porous plug 150. The dense columnar solid member 152 is coaxial with the resin porous plug 150 and extends from an upper surface 150a of the resin porous plug 150 to a lower surface 150b. In this case, the dense columnar solid member 152 serves as a core. Accordingly, the resin porous plug 150 is easily press-fitted into the plug insertion hole, and the height of the upper surface of the resin porous plug 150 can be precisely adjusted. The dense columnar solid member 152 may be contained so as not to extend through the resin porous plug 150 in the up-down direction. The material of the dense columnar solid member 152 is not particularly limited provided that the material is dense and may be, for example, ceramic or resin (for example, hard resin).

The resin porous plug 250 in FIG. 6 contains a dense cylindrical hollow member 252 that has a diameter smaller than that of the resin porous plug 250, that is inserted from a lower surface 250b of the resin porous plug 250, and that does not extend through an upper surface 250a of the resin porous plug 250. The dense cylindrical hollow member 252 is coaxial with the resin porous plug 250. In this case, the dense cylindrical hollow member 252 serves as a core. Accordingly, the resin porous plug 250 is easily press-fitted into the plug insertion hole, and the height of the upper surface of the resin porous plug 250 can be precisely adjusted. The gas mainly passes through an upper portion of the resin porous plug 250 (a portion above the dense cylindrical hollow member 252), and accordingly, the pressure loss of the gas can be reduced. The material of the dense cylindrical hollow member 252 is not particularly limited provided that the material is dense and may be, for example, ceramic or resin (for example, hard resin).

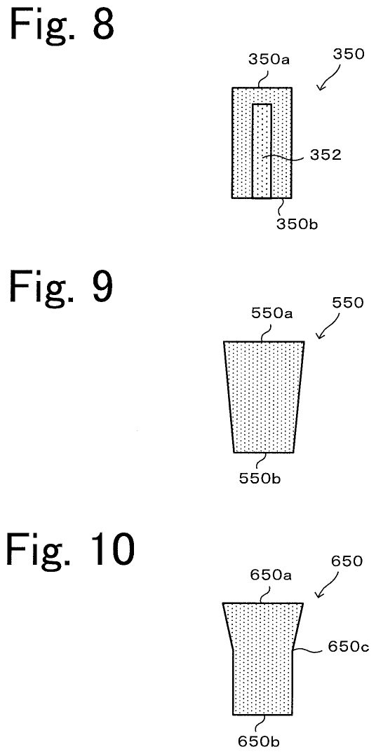

The resin porous plug 350 in FIG. 7 contains a columnar porous member 352 that has porosity higher than that of the resin porous plug 350. The columnar porous member 352 is coaxial with the resin porous plug 350 and extends from an upper surface 350a of the resin porous plug 350 to a lower surface 350b. In this case, the gas mainly passes through the columnar porous member 352, and accordingly, the pressure loss of the gas can be reduced. As illustrated in FIG. 8, the columnar porous member 352 may be contained so as not to extend through the resin porous plug 350 in the up-down direction or so as to be inserted from the lower surface 350b and so as not to extend through the upper surface 350a here. The material of the columnar porous member 352 is not particularly limited provided that the material is porous and may be, for example, ceramic or resin.

According to the embodiment described above, the resin porous plugs 50 that have a columnar shape are used. However, resin porous plugs 550 and 650 that have shapes illustrated in FIG. 9 to FIG. 10 may be used instead.

The resin porous plug 550 in FIG. 9 has an inversely truncated cone shape in which the area of a lower surface 550b is smaller than the area of an upper surface 550a. In the case where the resin porous plug 550 is used, the shape of the plug insertion hole is changed into a shape suitable for this.

The resin porous plug 650 in FIG. 10 has a columnar shape in a range from a lower surface 650b to an intermediate position 650c (a predetermined height) and an inversely truncated cone shape in a range from the intermediate position 650c to an upper surface 650a. In the case where the resin porous plug 650 is used, the shape of the plug insertion hole is changed into a shape suitable for this.

The resin porous plugs 550 and 650 in FIG. 9 and FIG. 10 may be modified as illustrated in FIG. 5 to FIG. 8.

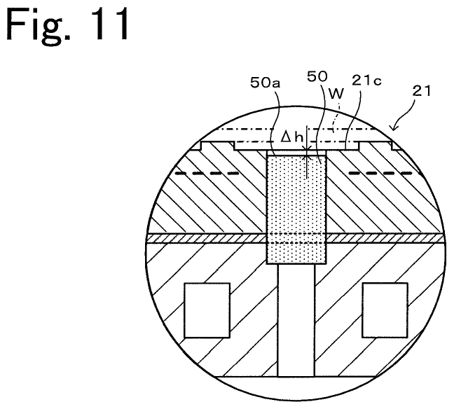

According to the embodiment described above, the upper surfaces 50a of the resin porous plugs 50 and the reference surface 21c of the wafer placement surface 21 are flush with each other but are not particularly limited thereto. For example, as illustrated in FIG. 11, a difference Δh obtained by subtracting the height of the upper surface 50a of each resin porous plug 50 from the height of the reference surface 21c of the wafer placement surface 21 may be 0.5 mm or less (preferably 0.2 mm or less, more preferably 0.1 mm or less). In other words, the upper surfaces 50a of the resin porous plugs 50 may be lower than the reference surface 21c of the wafer placement surface 21 by 0.5 mm or less (preferably 0.2 mm or less, more preferably 0.1 mm or less). Also, this enables the heights of the spaces between the lower surface of the wafer W and the upper surfaces 50a of the resin porous plugs 50 to be relatively low. Accordingly, arc discharge can be prevented from occurring in the spaces.

According to the embodiment described above, an electrostatic electrode is taken as an example of the electrode 22 that is contained in the ceramic plate 20, but this is not a particular limitation. For example, a heater electrode (a resistance heating element) may be contained in the ceramic plate 20, or a RF electrode may be contained therein, instead of or in addition to the electrode 22.

According to the embodiment described above, the ceramic plate 20 and the cooling plate 30 are joined to each other by the metal joining layer 40. A resin adhesive layer may be used instead of the metal joining layer 40. In this case, the cooling plate 30 corresponds to the conductive base according to the present invention.

The application claims priority to Japanese Patent Application No. 2022-001652 filed in the Japan Patent Office on Jan. 7, 2022, the entire contents of which are incorporated herein by reference.

What is claimed is:

1. A member for semiconductor manufacturing apparatus comprising:
a ceramic plate that has an upper surface including a wafer placement surface; and
a resin porous plug that has an upper surface that is exposed from the wafer placement surface, that is press-fitted and secured in a plug insertion hole that extends through the ceramic plate in an up-down direction, and that allows gas to flow.

2. The member for semiconductor manufacturing apparatus according to claim 1,
wherein the ceramic plate has a conductive base on a lower surface, and
wherein the resin porous plug is in contact with the conductive base.

3. The member for semiconductor manufacturing apparatus according to claim 1,
wherein the resin porous plug contains a dense columnar solid member that has a diameter smaller than that of the resin porous plug.

4. The member for semiconductor manufacturing apparatus according to claim 1,
wherein the resin porous plug contains a dense cylindrical hollow member that has a diameter smaller than that of the resin porous plug, that is inserted from a lower surface of the resin porous plug, and that does not extend through an upper surface of the resin porous plug.

5. The member for semiconductor manufacturing apparatus according to claim 1,
wherein the resin porous plug contains a columnar porous member that has porosity higher than that of the resin porous plug.

6. The member for semiconductor manufacturing apparatus according to claim 1,
wherein the wafer placement surface has a large number of small projections that support a wafer, and
wherein the upper surface of the resin porous plug is lower than upper surfaces of the small projections.

7. The member for semiconductor manufacturing apparatus according to claim 6,
wherein the upper surface of the resin porous plug is flush with a reference surface of the wafer placement surface on which the small projections are not formed or is lower than the reference surface by 0.5 mm or less.
